(19) United States
(12) Patent Application Publication
(10) Pub. No.: US 2024/0234607 A9
(43) Pub. Date: Jul. 11, 2024

(54) ANTI-SHADING PHOTOVOLTAIC CELL ASSEMBLY

(71) Applicant: JIANGSU CLELO TECHNOLOGIES CO., LTD., Changshu (CN)

(72) Inventors: Leizhen Hu, Changshu City (CN); Huiguo Zhang, Changshu City (CN); Silin Meng, Dongtai City (CN); Changrong Zhang, Changshu City (CN); Zhiguang Zhang, Hefeng County (CN)

(21) Appl. No.: 18/489,749

(22) Filed: Oct. 18, 2023

(30) Foreign Application Priority Data
Oct. 21, 2022 (CN) 202222789696.3

(51) Int. Cl. H01L 31/05

(52) U.S. Cl. CPC H01L 31/0508

(57) ABSTRACT

An anti-shading photovoltaic cell assembly and methods for making and using same. The assembly includes a cell layer with N cell strings connected in series. Each of the cell strings comprises M cell modules connected in series, and each of the cell modules comprises P solar cells connected in parallel. Each of the solar cells has a light-receiving surface, a rear surface, and a plurality of sides located between the light-receiving surface and the rear surface. The plurality of sides include a first side and an opposite second side. The first sides of the P solar cells in each of the cell modules are connected through a first solder ribbon, and the second sides of the P solar cells in each of the cell modules are connected through a second solder ribbon. Whereby, the light-receiving areas on front and back surfaces of the assembly are increased.

### CROSS-REFERENCE TO RELATED APPLICATIONS

This application claims the benefit of, and priority under 35 U.S.C. § 119 to, Chinese Utility Model Patent Application No. 202222789696.3, filed Oct. 21, 2022, the disclosure of which is hereby incorporated herein by reference in its entirety and for all purposes.

### FIELD

The present disclosure relates to the photovoltaic field and more particularly, but not exclusively, to an anti-shading photovoltaic cell assembly.

### BACKGROUND

With the continuous upgrading of photovoltaic cell and assembly technologies, a bifacial technology and a super multi-busbar technology have emerged, and various auxiliary materials have also been upgraded. For example, photovoltaic solder ribbons have developed from the original rectangular shape to the current round shape and are developing toward a smaller size. Currently, solder ribbon connection is still the mainstream photovoltaic assembly manufacturing process. To maximize a light-receiving area on the front surface of the assembly, a metal wrap through (MWT) back-contact cell has been developed. However, such MWT cells require high costs and still cannot maximize the light-receiving area on the front and back surfaces at the same time, resulting in low output power and a low power generation capacity.

### SUMMARY

An aspect of the disclosure relates to an improved anti-shading photovoltaic cell assembly and methods for making and using the same. By use of side soldering, a light-receiving area of the photovoltaic cell assembly is increased, thereby increasing the output power and the power generation capacity.

An anti-shading photovoltaic cell assembly is provided, including a cell layer comprising N cell strings connected in series, each of the cell strings comprises M cell modules connected in series, each of the cell modules comprises P solar cells connected in parallel, each of the solar cells has a light-receiving surface, a rear surface, and a plurality of sides located between the light-receiving surface and the rear surface, the plurality of sides comprising a first side and a second side being opposite to the first side, and the first sides of the P solar cells in each of the cell modules are connected through a first solder ribbon, and the second sides of the P solar cells in each of the cell modules are connected through a second solder ribbon.

In some embodiments, the anti-shading photovoltaic cell assembly, further comprising a front panel and a back panel, the cell layer is encapsulated between the front panel and the back panel.

In some embodiments, N comprises a positive integer that is greater than or equal to one.

In some embodiments, M comprises a positive integer that is greater than or equal to two, and wherein P comprises a positive integer that is greater than or equal to two.

In some embodiments, every two adjacent cell modules in each of the cell strings are connected in series through the first solder ribbon or the second solder ribbon.

In some embodiments, the first sides of a first one of the adjacent cell modules are connected to the first sides of a second one of the adjacent cell modules through the first solder ribbon.

In some embodiments, the N cell strings are connected in series through a busbar, and the busbar is connected between the first solder ribbons of every two adjacent cell strings.

In some embodiments, the second sides of a first one of the adjacent cell modules are connected to the second sides of a second one of the adjacent cell modules through the second solder ribbon.

In some embodiments, the N cell strings are connected in series through a busbar, and the busbar is connected between the second solder ribbons of every two adjacent cell strings.

In some embodiments, the first solder ribbon is soldered to the first sides of the P solar cells in each of the cell modules, and wherein the second solder ribbon is soldered to the second sides of the P solar cells in each of the cell modules.

In some embodiments, each of the solar cells comprises a front electrode located on the light-receiving surface and a rear electrode located on the rear surface, one of the front electrode and the rear electrode being conductively connected to the first solder ribbon, and the other one of the front electrode and the rear electrode being conductively connected to the second solder ribbon.

In some embodiments, an upper portion of the first solder ribbon or an upper portion of the second solder ribbon does not extend beyond the light-receiving surfaces of the solar cells, and wherein a bottom portion of the first solder ribbon or a bottom portion of the second solder ribbon does not extend beyond the rear surfaces of the solar cells.

In some embodiments, the first sides of the P solar cells in each of the cell modules are parallel with the second sides of the P solar cells in each of the cell modules.

In some embodiments, the M cell modules of each of the cell strings are arranged sequentially along the first sides of the P solar cells.

In some embodiments, the P solar cells of each of the cell modules are arranged sequentially along the first sides.

In some embodiments, the N cell strings are arranged on one side of the first sides of the P solar cells along a direction perpendicular to the first sides.

In some embodiments, a spacing between any two adjacent solar cells is less than or equal to one half millimeter.

In some embodiments, a spacing between any two adjacent cell modules is less than or equal to one half millimeter.

A method for assembling anti-shading photovoltaic cells is provided, including: connecting N cell strings in series to form a cell layer, each of the cell strings comprises M cell modules connected in series, each of the cell modules comprises P solar cells connected in parallel, each of the solar cells has a light-receiving surface, a rear surface, and a plurality of sides located between the light-receiving surface and the rear surface, the plurality of sides comprising a first side and a second side being opposite to the first side, and the first sides of the P solar cells in each of the cell modules are connected through a first solder ribbon, and the second sides of the P solar cells in each of the cell modules are connected through a second solder ribbon.

In some embodiments, further comprising encapsulating the cell layer between a front panel and a back panel.

The foregoing solutions of the disclosure have the following advantages.

In the disclosure, because the sides of the solar cells are connected through the solder ribbons, front and rear surfaces of the solar cells are not blocked by the solder ribbon. In addition, because the cells are connected in parallel and then in series, the light-receiving areas on the front and back surfaces of the photovoltaic cell assembly are increased, thereby increasing the output power and the power generation capacity.

### BRIEF DESCRIPTION OF THE DRAWINGS

To describe the technical solutions of the disclosure more clearly, the following briefly describes the drawings required for describing the embodiments. Apparently, the drawings in the following description show merely some embodiments of the disclosure, and those of ordinary skill in the art may still derive other drawings from these drawings without creative efforts.

FIG. 1 is a cross-sectional view of a photovoltaic cell assembly according to an embodiment of the disclosure;

FIG. 2 is a schematic structural assembled view of a photovoltaic cell assembly according to an embodiment of the disclosure;

FIG. 3a is a structural diagram of a light-receiving surface of a cell string according to an embodiment of the disclosure;

FIG. 3b is a structural diagram of a rear surface of the cell string according to an embodiment of the disclosure; and

FIG. 4 is an equivalent circuit diagram of a photovoltaic cell assembly according to an embodiment of the disclosure.

In the drawings: 1—cell layer; 2—cell string; 3—cell module; 4—solar cell; 41—light-receiving surface; 42—rear surface; 43—first side; 44—second side; 5—first solder ribbon; 6—second solder ribbon; 7—busbar; 8—negative electrode lead-out terminal; 9—positive electrode lead-out terminal; 10—bypass diode; 11—isolation strip; 12—panel; 13—back panel; and 14—encapsulation layer.

### DETAILED DESCRIPTION OF THE PREFERRED EMBODIMENTS

Example embodiments of the disclosure will be described in detail below in conjunction with the accompanying drawings so that advantages and features of the disclosure can be more easily understood by those skilled in the art. It should be noted herein that the description of these embodiments is used for helping understand the disclosure but is not intended to limit the disclosure. In addition, the technical features involved in the embodiments of the disclosure described below may be combined with each other as long as they do not conflict with each other.

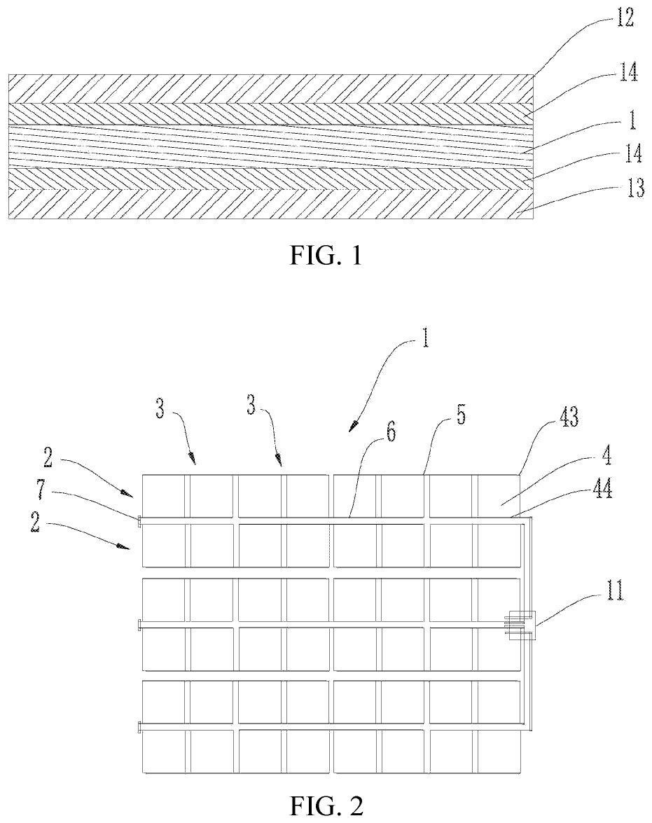

As shown in FIG. 1, an anti-shading photovoltaic cell assembly according to an embodiment includes a (front) panel 12, a back panel 13, a cell layer 1 encapsulated between the panel and the back panel, an encapsulation layer 14 arranged between the panel 12 and the cell layer 1, and an encapsulation layer 14 arranged between the back panel 13 and the cell layer 1. The cell layer 1 includes N cell strings 2 connected in series. Each of the cell strings 2 includes M cell modules 3 connected in series. Each of the cell modules 3 includes P solar cells 4 connected in parallel. N is greater than or equal to one, and M and P are both greater than or equal to two.

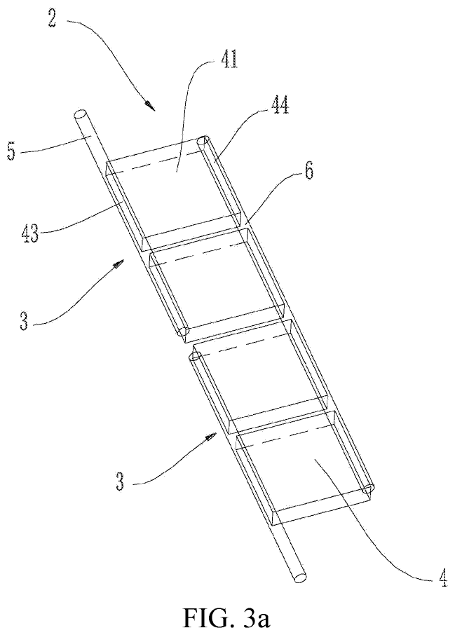

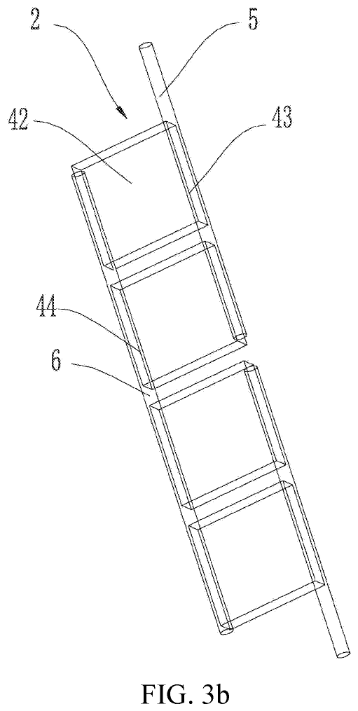

As shown in FIG. 2 and FIGS. 3a-b, each of the solar cells 4 has a light-receiving surface 41, a rear surface 42, and a plurality of sides located between the light-receiving surface 41 and the rear surface 42. The plurality of sides include a first side 43 and a second side 44 opposite to each other. The first side 43 and the second side 44 are parallel to each other. The first sides 43 of the P solar cells 4 of each cell module 3 are connected through a first solder ribbon 5, and the second sides 44 of the P solar cells 4 of each cell module 3 are connected through a second solder ribbon 6. Every two adjacent cell modules 3 in each cell string 2 are connected in series through the first solder ribbon 5 or the second solder ribbon 6. Specifically, the first sides 43 of one of the cell modules 3 are connected to the first sides 43 of a previous cell module 3 through the same first solder ribbon 5, and the second sides 44 of the one of the cell modules 3 are connected to the second sides 44 of a next cell module 3 through the same second solder ribbon 6. Preferably, the connection method is used for side soldering in this embodiment, i.e., adjacent cell modules share one solder ribbon, thereby further reducing costs of the assembly.

As shown in FIG. 2, in this embodiment, the M cell modules 3 of each cell string 2 are arranged sequentially along the first side 43, and the P solar cells 4 of each cell module 3 are arranged sequentially along the first side 43, and the N cell strings 2 are arranged on one side of the first side 43 along a direction perpendicular to the first side 43. Preferably, a spacing between any two adjacent solar cells 4 is less than or equal to one half millimeter (0.5 mm), a spacing between any two adjacent cell modules 3 is less than or equal to one half millimeter (0.5 mm), and a spacing between any two adjacent cell strings 2 is less than or equal to one half millimeter (0.5 mm). In some other embodiments, the spacing between any two adjacent solar cells 4 may be greater than one half millimeter (0.5 mm) or a mixed-spacing arrangement may be adopted, the spacing between any two adjacent solar cell modules 3 may be greater than one half millimeter (0.5 mm) or a mixed-spacing arrangement may be adopted, and the spacing between any two adjacent cell strings 2 may be greater than one half millimeter (0.5 mm) or a mixed-spacing arrangement may be adopted.

Preferably, the first solder ribbon 5 is soldered to the first side 43 of the solar cell 4, and the second solder ribbon 6 is soldered to the second side 44 of the solar cell 4. In some other embodiments, the solder ribbon may alternatively be connected to the solar cell by adhesive dispensing. An upper portion of the first solder ribbon 5 or the second solder ribbon 6 does not extend beyond the light-receiving surface of the solar cell 4 and a bottom portion of the first solder ribbon 5 or the second solder ribbon 6 does not extend beyond a rear surface of the solar cell 4.

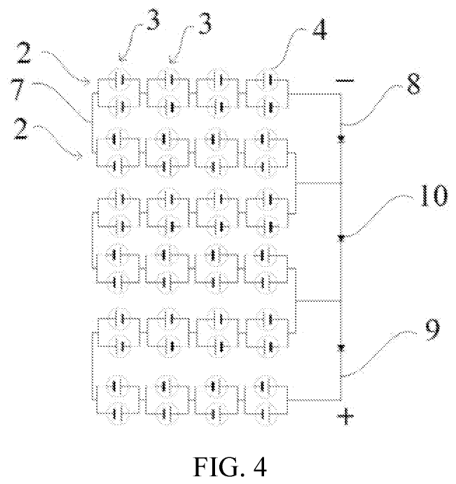

FIG. 4 is an equivalent circuit diagram of the photovoltaic cell assembly in this embodiment. The N cell strings 2 are insulated by isolation bars and connected in series through a busbar 7 to jointly provide an output, and are respectively connected to a negative electrode through a negative electrode lead-out terminal 8 and connected to a positive electrode through a positive electrode lead-out terminal 9. The busbar 7 is connected between the first solder ribbons 5 or the second solder ribbons 6 of every two adjacent cell strings 2. The cells are connected in parallel and then in series, and a plurality of bypass diodes 10 are distributed to ensure that the components can operate even under special situations. Each solar cell 4 includes a front electrode located on the light-receiving surface 41 and a rear electrode located on the rear surface 42. One of the front electrode and the rear electrode is conductively connected to the first solder ribbon 5, and the other one of the front electrode and the rear electrode is conductively connected to the second solder ribbon 6.

In this embodiment, a voltage of the assembly may be changed to adapt to different usage scenarios. The anti-shading photovoltaic cell assembly can be applied to building integrated photovoltaics (BIPVs) and conventional crystalline silicon assemblies, such as a heterojunction cell, a monocrystalline silicon TOPCon cell, a passivated emitter rear contact (PERC) solar cell. In addition, the photovoltaic cell assembly in this embodiment is compatible with cells of various sizes and types, such as 158 cells, 166 cells, 182 cells, and 210 cells.

To sum up, the disclosure has following advantages:

The use of side soldering and better layout can increase the light-receiving areas on the front and back surfaces of the assembly, thereby increasing the output power and the power generation capacity. The solder ribbons and the solar cell are connected in the same plane, there is no solder ribbon inserted between the cells, and the solder ribbon is separated from a force receiving surface of the cell, thereby effectively reducing the risks caused by cell cracking. Because the cell layer is encapsulated between the panel and the back panel, there is no solder ribbon on the front and back surfaces, so that the thickness of an ethylene-vinyl acetate copolymer (EVA) film or polyolefin (POE) film can be reduced, thereby reducing costs of the assembly.

As used in the specification and claims, the terms “comprise”, “include” and variants thereof merely imply the inclusion of clearly identified steps and elements, such steps and elements are not to be construed as an exclusive enumeration, and the method or device may also include other steps or elements. The term “and/or” used in the specification includes any one or any combination of one or more related listed items.

It should be noted that, unless otherwise particularly specified, that a feature is “fixed” or “connected” to another feature may mean that the feature is directly fixed or connected to the another feature, or indirectly fixed or connected to the another feature. In addition, the terms such as up, down, left, and right used in the disclosure are merely based on the relationship between relative positions of various components of the disclosure in the drawings.

As a preface to the detailed description, it should be noted that, as used in this specification and the appended claims, the singular forms “a”, “an” and “the” include plural referents, unless the context clearly dictates otherwise.

The foregoing embodiment is merely for illustrating the technical concept and features of the disclosure, is an example embodiment for enabling those skilled in the art to understand and implement the content of the disclosure, and is not intended to limit the protection scope of the disclosure. Any equivalent variation or modification made based on the principles of the disclosure shall fall within the protection scope of the disclosure.

What is claimed is:

1. An anti-shading photovoltaic cell assembly, comprising:
a cell layer comprising N cell strings connected in series,
wherein each of the cell strings comprises M cell modules connected in series,
wherein each of the cell modules comprises P solar cells connected in parallel,
wherein each of the solar cells has a light-receiving surface, a rear surface, and a plurality of sides located between the light-receiving surface and the rear surface, the plurality of sides comprising a first side and a second side being opposite to the first side, and
wherein the first sides of the P solar cells in each of the cell modules are connected through a first solder ribbon, and the second sides of the P solar cells in each of the cell modules are connected through a second solder ribbon.

2. The anti-shading photovoltaic cell assembly according to claim 1, further comprising a front panel and a back panel, wherein the cell layer is encapsulated between the front panel and the back panel.

3. The anti-shading photovoltaic cell assembly according to claim 1, wherein N comprises a positive integer that is greater than or equal to one.

4. The anti-shading photovoltaic cell assembly according to claim 1, wherein M comprises a positive integer that is greater than or equal to two, and wherein P comprises a positive integer that is greater than or equal to two.

5. The anti-shading photovoltaic cell assembly according to claim 1, wherein every two adjacent cell modules in each of the cell strings are connected in series through the first solder ribbon or the second solder ribbon.

6. The anti-shading photovoltaic cell assembly according to claim 5, wherein the first sides of a first one of the adjacent cell modules are connected to the first sides of a second one of the adjacent cell modules through the first solder ribbon.

7. The anti-shading photovoltaic cell assembly according to claim 6, wherein the N cell strings are connected in series through a busbar, and the busbar is connected between the first solder ribbons of every two adjacent cell strings.

8. The anti-shading photovoltaic cell assembly according to claim 5, wherein the second sides of a first one of the adjacent cell modules are connected to the second sides of a second one of the adjacent cell modules through the second solder ribbon.

9. The anti-shading photovoltaic cell assembly according to claim 8, wherein the N cell strings are connected in series through a busbar, and the busbar is connected between the second solder ribbons of every two adjacent cell strings.

10. The anti-shading photovoltaic cell assembly according to claim 1, wherein the first solder ribbon is soldered to the first sides of the P solar cells in each of the cell modules, and wherein the second solder ribbon is soldered to the second sides of the P solar cells in each of the cell modules.

11. The anti-shading photovoltaic cell assembly according to claim 1, wherein each of the solar cells comprises a front electrode located on the light-receiving surface and a rear electrode located on the rear surface, one of the front electrode and the rear electrode being conductively connected to the first solder ribbon, and the other one of the front electrode and the rear electrode being conductively connected to the second solder ribbon.

12. The anti-shading photovoltaic cell assembly according to claim 1, wherein an upper portion of the first solder ribbon or an upper portion of the second solder ribbon does not extend beyond the light-receiving surfaces of the solar cells, and wherein a bottom portion of the first solder ribbon or a bottom portion of the second solder ribbon does not extend beyond the rear surfaces of the solar cells.

13. The anti-shading photovoltaic cell assembly according to claim 1, wherein the first sides of the P solar cells in each of the cell modules are parallel with the second sides of the P solar cells in each of the cell modules.

14. The anti-shading photovoltaic cell assembly according to claim 13, wherein the M cell modules of each of the cell strings are arranged sequentially along the first sides of the P solar cells.

15. The anti-shading photovoltaic cell assembly according to claim 14, wherein the P solar cells of each of the cell modules are arranged sequentially along the first sides.

16. The anti-shading photovoltaic cell assembly according to claim 15, wherein the N cell strings are arranged on one side of the first sides of the P solar cells along a direction perpendicular to the first sides.

17. The anti-shading photovoltaic cell assembly according to claim 1, wherein a spacing between any two adjacent solar cells is less than or equal to one half millimeter.

18. The anti-shading photovoltaic cell assembly according to claim 1, wherein a spacing between any two adjacent cell modules is less than or equal to one half millimeter.

19. A method for assembling anti-shading photovoltaic cells, comprising:
connecting N cell strings in series to form a cell layer,
wherein each of the cell strings comprises M cell modules connected in series,
wherein each of the cell modules comprises P solar cells connected in parallel,
wherein each of the solar cells has a light-receiving surface, a rear surface, and a plurality of sides located between the light-receiving surface and the rear surface, the plurality of sides comprising a first side and a second side being opposite to the first side, and
wherein the first sides of the P solar cells in each of the cell modules are connected through a first solder ribbon, and the second sides of the P solar cells in each of the cell modules are connected through a second solder ribbon.

20. The method according to claim 19, further comprising encapsulating the cell layer between a front panel and a back panel.
